(19) United States
(12) Patent Application Publication
(10) Pub. No.: US 2026/0047458 A1
(43) Pub. Date: Feb. 12, 2026

(54) SUBSTRATE INCLUDING DUMMY THROUGH-VIA

(71) Applicant: Samsung Electronics Co., Ltd., Suwon-si (KR)

(72) Inventor: Chilwoo Kwon, Suwon-si (KR)

(21) Appl. No.: 19/180,557

(22) Filed: Apr. 16, 2025

(30) Foreign Application Priority Data
Aug. 7, 2024 (KR) 10-2024-0105447

(51) Int. Cl. H01L 23/498

(52) U.S. Cl. CPC H01L 23/49827; H01L 23/49816

(57) ABSTRACT

A substrate includes a core layer including an active region in which a semiconductor chip is mounted and a dummy region, surrounding the active region, through-vias disposed in the active region, the through-vias passing through the core layer, dummy through-vias disposed in the dummy region, the dummy through-vias passing through the core layer, upper connection pads disposed on an upper surface of the core layer in the active region, each of the upper connection pads electrically connected to a respective one of the through-vias, upper support pads disposed on the upper surface of the core layer in the dummy region, each of the upper support pads in contact with a respective one of the dummy through-vias, and lower support pads disposed on a lower surface of the core layer in the dummy region, each of the lower support pads in contact with a respective one of the dummy through-vias.

### CROSS-REFERENCE TO RELATED APPLICATION(S)

This application claims benefit of priority to Korean Patent Application No. 10-2024-0105447 filed on Aug. 7, 2024, in the Korean Intellectual Property Office, the disclosure of which is incorporated herein by reference in its entirety.

### BACKGROUND

The present inventive concept relates to a substrate including a dummy through-via.

As demand for the implementation of high performance, high speed, and/or multifunctionalization of semiconductor devices increases, a degree of integration of semiconductor devices has been increasing. In manufacturing semiconductor devices having a fine pattern corresponding to the trend for a high degree of integration of semiconductor devices, it is necessary to implement patterns having a fine width or a fine separation distance. Accordingly, a substrate on which a semiconductor chip is mounted has been continuously reduced in thickness. Therefore, there is demand for a technology for preventing damage or warpage of a substrate during a semiconductor package manufacturing process.

### SUMMARY

An aspect of the present inventive concept provides a substrate including a dummy through-via disposed in a dummy region and an upper support pad and a lower support pad connected thereto.

According to an aspect of the present inventive concept, there is provided a substrate including a core layer including an active region in which a semiconductor chip is mounted and a dummy region, surrounding the active region, through-vias disposed in the active region, the through-vias passing through the core layer, dummy through-vias disposed in the dummy region, the dummy through-vias passing through the core layer, upper connection pads disposed on an upper surface of the core layer in the active region, each of the upper connection pads electrically connected to a respective one of the through-vias, upper support pads disposed on the upper surface of the core layer in the dummy region, each of the upper support pads in contact with a respective one of the dummy through-vias, and lower support pads disposed on a lower surface of the core layer in the dummy region, each of the lower support pads in contact with a respective one of the dummy through-vias.

According to another aspect of the present inventive concept, there is provided a substrate including a core layer including an active region in which a semiconductor chip is mounted and a dummy region, surrounding the active region, through-vias disposed in the active region, the through-vias passing through the core layer, dummy through-vias disposed in the dummy region, the dummy through-vias passing through the core layer, an upper structure disposed on an upper surface of the core layer, and a lower structure disposed on a lower surface of the core layer. The upper structure may include upper connection pads with each of the upper connection pads in contact with a respective one of the through-vias, and an upper support structure in contact with the dummy through-vias. The lower structure may include a lower support structure in contact with the dummy through-vias.

According to another aspect of the present inventive concept, there is provided a substrate including a core layer including an active region in which a semiconductor chip is mounted and a dummy region, surrounding the active region, through-vias disposed in the active region, the through-vias passing through the core layer, dummy through-vias disposed in the dummy region, the dummy through-vias passing through the core layer, upper connection pads disposed on an upper surface of the core layer in the active region, each of the upper connection pads electrically connected to a respective one of the through-vias, upper support pads disposed on the upper surface of the core layer in the dummy region, each of the upper support pads in contact with a respective one of the dummy through-vias, and lower support pads disposed on a lower surface of the core layer in the dummy region, each of the lower support pads in contact with a respective one of the dummy through-vias. The core layer may include dummy through-holes passing through the core layer in the dummy region. Each of the dummy through-vias may fill a respective one of the dummy through-holes. The dummy through-vias may have a first width at a first vertical level, a second width greater than the first width at a second vertical level higher than the first vertical level, and a third width greater than the first width at a third vertical level lower than the first vertical level.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view of a substrate according to an example embodiment;

FIG. 2 is an enlarged partial view of the substrate illustrated in FIG. 1;

FIG. 3 is a vertical cross-sectional view taken along line I-I′ of the substrate illustrated in FIG. 2;

FIG. 4 is an enlarged partial view of the substrate illustrated in FIG. 1;

FIG. 5 is a vertical cross-sectional view of the substrate illustrated in FIG. 4, taken along line II-II′;

FIG. 6 is a plan view of the substrate illustrated in FIG. 5;

FIG. 7A is a plan view of a substrate according to an example embodiment;

FIG. 7B is a vertical cross-sectional view of the substrate illustrated in FIG. 7A, taken along line II-II′;

FIG. 7C is a plan view of the substrate illustrated in FIG. 7B;

FIGS. 8 to 10 are plan views of a substrate according to example embodiments;

FIGS. 11 to 12 are vertical cross-sectional views of a substrate according to example embodiments; and

FIGS. 13A to 13D are diagrams illustrating a method of manufacturing a semiconductor package according to an example embodiment.

### DETAILED DESCRIPTION

Hereinafter, example embodiments of the present inventive concept will be described with reference to the accompanying drawings. The inventive concept may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

As used herein, the term “dummy” is used to refer to a component that has the same or similar structure and shape as other components but does not have a substantial function in the operation of a circuit (e.g., to convey information). The “dummy” element may only exist as a pattern in the device. In some instances, a “dummy” element may be electrically floated, or may be connected to various voltage sources but otherwise not provide the same functionality of the non-dummy element it represents.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim. Items described in the singular herein may be provided in plural, as can be seen, for example, in the drawings. Thus, the description of a single item that is provided in plural should be understood to be applicable to the remaining plurality of items unless context indicates otherwise.

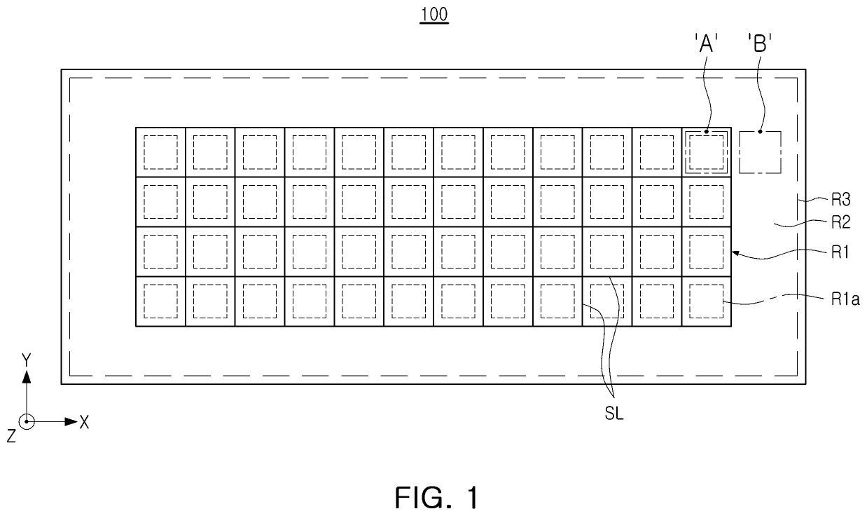

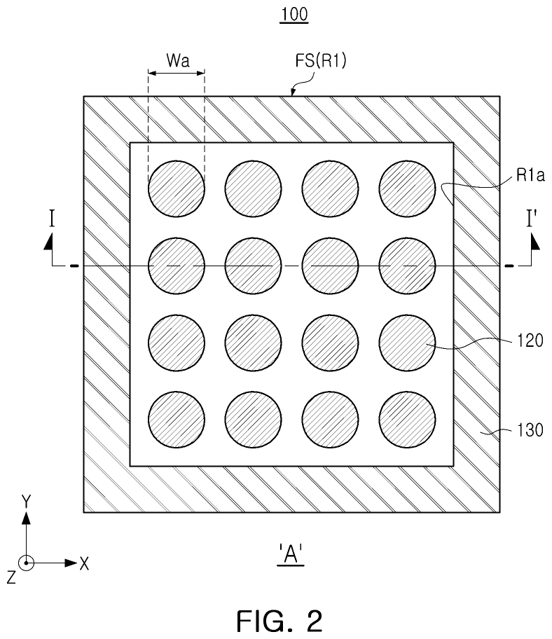

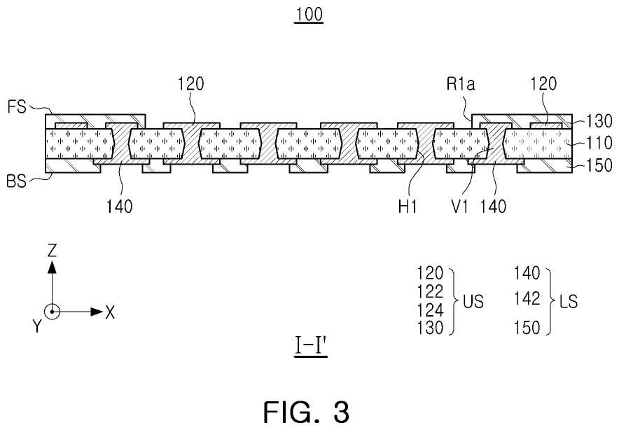

FIG. 1 is a plan view of a substrate according to an example embodiment. FIG. 2 is an enlarged view of a portion of the substrate illustrated in FIG. 1. FIG. 2 may correspond to region “A” identified in FIG. 1. FIG. 3 is a vertical cross-sectional view of the substrate illustrated in FIG. 2, taken along line I-I′.

Referring to FIGS. 1 to 3, a substrate 100 according to an example embodiment of the present inventive concept may be a printed circuit board (PCB). The term “substrate” may denote a base substrate (e.g., an initial semiconductor substrate forming the base of the wafer in the final wafer product, such as a bulk semiconductor substrate (e.g., formed of crystalline silicon), an silicon on insulator (SOI) substrate, etc.), or a stack structure including such a base substrate and layers formed on the substrate. For example, the substrate 100 may be a PCB for a molded underfill (MUF). In an example embodiment, the substrate 100 may have a strip structure extending in a horizontal direction (X-direction). A core layer 110 of the substrate 100 may include an active region R1, a dummy region R2, and a peripheral region R3.

The active region R1 may be a region in which semiconductor chips are mounted. A plurality of semiconductor chips may be mounted in the active region R1. After a molding process is performed, the active region R1 may be individualized along a scribe lane SL to manufacture a semiconductor package (e.g., the active region R1 may be cut along a scribe lane to separate the active region R1 into individual semiconductor packages).

The dummy region R2 may surround the active region R1. The semiconductor chips may not be mounted in the dummy region R2 (e.g., the dummy region R2 may be a region in which semiconductor chips are not mounted). The active region R1 and the dummy region R2 may be sealed by an encapsulant in the molding process. In the plan view of FIG. 1, it is illustrated that the active region R1 and the dummy region R2 have a rectangular shape, but the present inventive concept is not limited thereto.

Bonding regions R1a, which are each a region in which a semiconductor of the plurality of semiconductor chips are mounted may be disposed in the active region R1. In FIG. 1, the bonding regions R1a may be indicated by dotted lines in the active region R1. Scribe lanes SL may be indicated by a solid line and may form a solid-line rectangle. The solid line rectangles may each correspond to a single semiconductor package including a semiconductor chip that may be formed after the molding process. The scribe lanes SL may correspond to lines on which cutting is performed in a sawing/sorter process for individualizing the semiconductor chips into each semiconductor package after a molding process for sealing the semiconductor chips with an encapsulant. For example, the active region R1 may be a region that remains as a portion of an individual semiconductor package after the semiconductor package is completed, and the dummy region R2 may be a region that does not form a semiconductor package.

The peripheral region R3 may surround the dummy region R2. In the peripheral region R3, a mark indicating information on a semiconductor chip to be mounted, a guide used in a subsequent process, marks for PCB alignment, and a guide hole may be disposed. The guide hole may be used as a recognition mark during a molding process, and may also be used as an alignment means during movement. Unit alignment marks, which may be a reference point of the scribe lanes SL, may be disposed in the active region R1.

FIGS. 2 and 3 are a plan view and a vertical cross-sectional view of the substrate 100 in the active region R1.

Referring further to FIGS. 2 and 3, the substrate 100 may include a core layer 110, an upper structure US, and a lower structure LS. In an example embodiment, the substrate 100 may be a substrate for a semiconductor package such as a PCB, an interposer substrate, a ceramic substrate, a tape interconnection substrate, or the like. In an example embodiment, the substrate 100 may be a PCB. For example, the core layer 110 of the substrate 100 may include a thermosetting resin such as an epoxy resin, a thermoplastic resin such as polyimide, or a photosensitive insulating layer. Specifically, the core layer 110 may include a material such as a prepreg, an Ajinomoto build-up film (ABF), FR-4, bismaleimide triazine (BT), and a photoimageable dielectric resin (PID). The substrate 100 may be formed using, for example, a copper clad laminate (CCL), an unclad CCL, a glass substrate, a ceramic substrate, or the like.

In the active region R1, the core layer 110 may include a through-hole H1. The through-hole H1 may pass through upper and lower surfaces of the core layer 110 and vertically extend from the upper surface to the lower surface. The substrate 100 may further include a through-via V1 disposed in the through-hole H1.

In an example embodiment, the through-hole H1 may have an hourglass shape. For example, a horizontal width of the through-hole H1 may decrease and then increase from the upper surface to the lower surface of the core layer 110.

In an example embodiment, the through-via V1 may entirely fill the through-hole H1. For example, the through-via V1 may have an hourglass shape (e.g., the through-via V1 may have a shape that is complementary to the shape of the through-hole H1). The horizontal width of the through-via V1 may decrease and then increase along a length from the upper surface to the lower surface of the core layer 110. Upper and lower surfaces of the through-via V1 may be coplanar with the upper and lower surfaces of the core layer 110, respectively.

The through-via V1 may include a conductive material. The through-via V1 may include, for example, a metal material including copper (Cu), aluminum (Al), silver (Ag), tin (Sn), gold (Au), nickel (Ni), lead (Pb), titanium (Ti), or alloys thereof.

The upper structure US may be disposed on the upper surface of the core layer 110. In the active region R1, the upper structure US may include an upper connection pad 120 and an upper protective layer 130. The upper connection pads 120 may be in contact with the upper surface of the core layer 110, and may be electrically connected to a corresponding through-via V1. In an example embodiment, at least one of the upper connection pads 120 may have an interconnection structure extending in a horizontal direction from the upper surface of the core layer 110. A shape, an arrangement structure, and the number of the upper connection pads 120 illustrated in FIG. 2 are examples, and are not limited thereto.

The upper connection pad 120 may include a conductive material. The upper connection pad 120 may include, for example, a metal material including copper (Cu), aluminum (Al), silver (Ag), tin (Sn), gold (Au), nickel (Ni), lead (Pb), titanium (Ti), or alloys thereof. In an example embodiment, the upper connection pad 120 may be formed simultaneously with the through-via V1, and may include a material the same as that of the through-via V1.

The upper protective layer 130 may partially cover the upper surface of the core layer 110, and may cover at least one of the upper connection pads 120. As described above, the substrate 100 may be a PCB for an MUF, an encapsulant such as an EMC may be disposed between a semiconductor chip mounted on the substrate 100 and the substrate 100, or an underfill may be omitted. That is, in the molding process, the encapsulant may cover the semiconductor chip and the substrate 100, and may flow into a space between the semiconductor chip and the substrate 100. The upper connection pads 120 in contact with the semiconductor chip may not be covered by the upper protective layer 130 such that the encapsulant may flow smoothly into the space between the semiconductor chip and the substrate 100, and upper and side surfaces of the upper connection pads 120 may be entirely exposed. For example, as illustrated in FIG. 3, the upper protective layer 130 may include a bonding region R1a exposing the upper connection pads 120. After a process of manufacturing semiconductor packages is completed, the bonding regions R1a may be positioned on a central portion of each semiconductor package, and the upper protective layer 130 may extend along an edge of each semiconductor package. The upper protective layer 130 may include, for example, a solder resist (SR).

The lower structure LS may be disposed on the lower surface of the core layer 110. In the active region R1, the lower structure LS may include a lower connection pad 140 and a lower protective layer 150. The lower connection pads 140 may be in contact with the lower surface of the core layer 110, and may be electrically connected to a corresponding through-via V1. In an example embodiment, at least one of the lower connection pads 140 may have an interconnection structure extending in a horizontal direction from the lower surface of the core layer 110.

The lower connection pad 140 may include a conductive material. The lower connection pad 140 may include, for example, a metal material including copper (Cu), aluminum (Al), silver (Ag), tin (Sn), gold (Au), nickel (Ni), lead (Pb), titanium (Ti), or alloys thereof. In an example embodiment, the lower connection pad 140 may be formed simultaneously with the through-via V1 and the upper connection pad 120, and may include a material the same as that of the through-via V1 and the upper connection pad 120 (e.g., the lower connection pad 140 may be formed in the same process as the through-via V1 and the upper connection pad 120). In an example, the through-via V1, the upper connection pad 120, and the lower connection pad 140 may include copper (Cu).

The lower protective layer 150 may partially cover the lower surface of the core layer 110, and may cover at least one of the lower connection pads 140. In an example embodiment, a volume of the lower protective layer 150 may be greater than a volume of the upper protective layer 130. In an example embodiment, in plan view, an area of the lower protective layer 150 may be greater than an area of the upper protective layer 130. For example, the substrate 100 according to example embodiments of the present inventive concept may be a PCB for an MUF, and the upper protective layer 130 may be relatively small area such that the encapsulant flows into a space between the substrate 100 and the semiconductor chip. For example, after an individual semiconductor package is manufactured, the area of the upper protective layer 130 may be in a range from about 20% to about 30% of the area of the semiconductor package.

An upper surface of the upper protective layer 130, the core layer 110 and the upper connection pads 120 exposed by the upper protective layer 130 may form a front surface FS of the substrate 100. A lower surface of the lower protective layer 150, the core layer 110 and the lower connection pads 140 exposed by the lower protective layer 150 may form a rear surface BS of the substrate 100.

The upper structure US and the lower structure LS illustrated in FIG. 3 are examples, and are not limited thereto. In an example embodiment, the upper connection pads 120 may be formed of a plurality of layers, and the lower connection pads 140 may be formed of a plurality of layers.

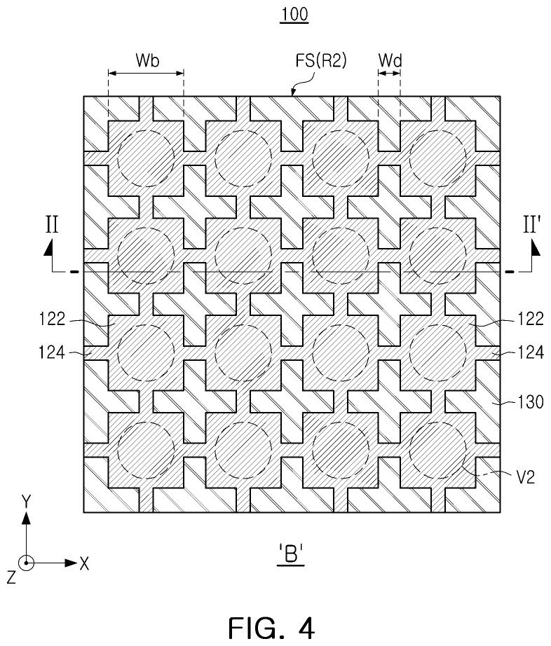

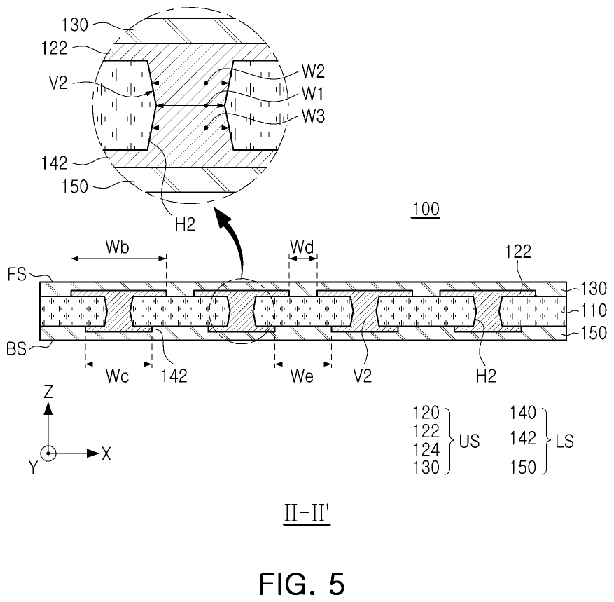

FIG. 4 is a partially enlarged view of the substrate illustrated in FIG. 1. FIG. 4 may correspond to region “B” illustrated in FIG. 1, and illustrates a front surface of the substrate. FIG. 5 is a vertical cross-sectional view of the substrate illustrated in FIG. 4, taken along line II-II′.

Referring to FIGS. 4 and 5, the upper structure US may be disposed on the core layer 110 in the dummy region R2, and the lower structure LS may be disposed below the core layer 110.

In the dummy region R2, the core layer 110 may include a dummy through-hole H2. The dummy through-hole H2 may pass through the upper and lower surfaces of the core layer 110 and vertically extend between the upper and lower surfaces. The substrate 100 may further include a dummy through-via V2 disposed in the dummy through-hole H2.

In an example embodiment, the dummy through-hole H2 may have a shape the same as or similar to that of the through-hole H1, and may have an hourglass shape. For example, when a horizontal width of the dummy through-hole H2 may decrease and then increase from the upper surface to the lower surface of the core layer 110. The dummy through-hole H2 may have a first width W1, a minimum value at a first vertical level, between the upper surface to the lower surface of the core layer 110. The dummy through-hole H2 may have a second width W2 greater than the first width W1 at a second vertical level higher than the first vertical level, and may have a third width W3 greater than the first width W1 at a third vertical level lower than the first vertical level.

In an example embodiment, the dummy through-via V2 may have a structure the same as or similar to that of the through-via V1, and may entirely fill the dummy through-hole H2 (e.g., the shape of the dummy through-via V2 may be complementary to the dummy through-hole H2). For example, the dummy through-via V2 may have an hourglass shape. The dummy through-via V2 may have a first width W1, a minimum value at a first vertical level, between the upper and lower surfaces of the core layer 110. The dummy through-via V2 may have a second width W2 greater than the first width W1 at a second vertical level higher than the first vertical level, and may have a third width W3 greater than the first width W1 at a third vertical level lower than the first vertical level. Upper and lower surfaces of the dummy through-via V2 may be coplanar with the upper and lower surfaces of the core layer 110, respectively.

The dummy through-via V2 may include a conductive material. The dummy through-via V2 may include, for example, a metal material including copper (Cu), aluminum (Al), silver (Ag), tin (Sn), gold (Au), nickel (Ni), lead (Pb), titanium (Ti), or alloys thereof.

In the present specification, the active region R1 and the dummy region R2 may be referred to as a first region and a second region, respectively. The through-via V1 and the dummy through-via V2 may be referred to as a first through-via and a second through-via, respectively. The through-hole H1 and the dummy through-hole H2 may also be referred to as a first through-hole and a second through-hole, respectively.

In the dummy region R2, the upper structure US may include upper support structures,. In an example embodiment, the upper support structures may include an upper support pad 122 and an upper support pattern 124. The upper support pads 122 may be in contact with the upper surface of the core layer 110, and at least one of the upper support pads 122 may be in contact with and connected to a corresponding dummy through-via V2. In an example embodiment, the upper support patterns 124 may be disposed between the upper support pads 122, and may connect adjacent upper support pads 122 to each other. At least one of the upper support patterns 124 may have an interconnection structure extending in a horizontal direction from the upper surface of the core layer 110.

In an example embodiment, the upper support pads 122 may be disposed in a grid pattern, and the upper support patterns 124 may extend between the upper support pads 122. Shapes, arrangement structures, and the numbers of the upper support pad 122 and the upper support pattern 124 illustrated in FIG. 4 are examples, and are not limited thereto. In an example embodiment, the upper support pad 122 may have a rectangular shape, a polygonal shape, a circular shape, or an elliptical shape. For ease of description, the upper support pads 122 and the upper support patterns 124 are illustrated in FIG. 4. However, as illustrated in FIG. 5, the upper support pads 122 and the upper support patterns 124 may be entirely covered by the upper protective layer 130.

The upper support pad 122 and the upper support pattern 124 may include, for example, a metal material including copper (Cu), aluminum (Al), silver (Ag), tin (Sn), gold (Au), nickel (Ni), lead (Pb), titanium (Ti), or alloys thereof. In an example embodiment, the upper support pad 122 and the upper support pattern 124 may be formed simultaneously with the dummy through-via V2, and may include a material the same as that of the dummy through-via V2 (e.g., the upper support pad 122 and the upper support pattern 124 may be formed in the same process as the dummy through-via V2). In an example embodiment, the upper support pad 122 and the upper support pattern 124 may have a thickness substantially equal to that of the upper connection pad 120.

In the dummy region R2, the upper protective layer 130 may entirely cover the upper surface of the core layer 110 and the upper support pads 122. In the dummy region R2, the upper surface of the core layer 110 and the upper support pads 122 may not be exposed.

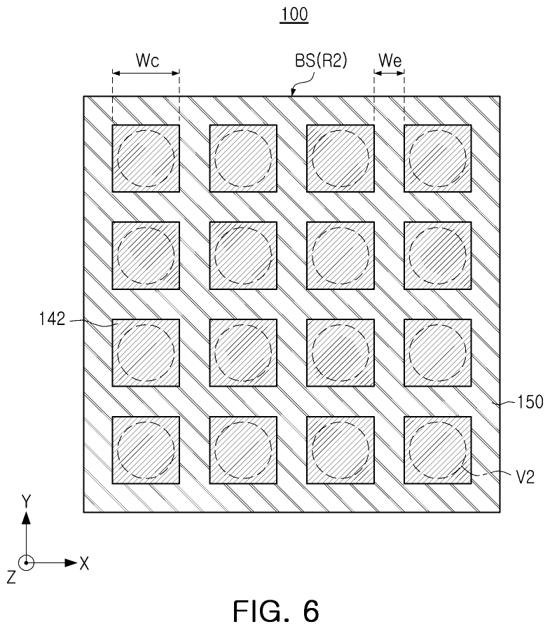

FIG. 6 is a plan view of the substrate illustrated in FIG. 5. FIG. 6 illustrates a rear surface BS of the substrate illustrated in FIG. 5.

Referring further to FIG. 6, in the dummy region R2, the lower structure LS may further include a lower support pad 142. At least one of the lower support pads 142 may be in contact with and connected to a corresponding dummy through-via V2. In an example embodiment, the lower support pads 142 may be disposed in a grid pattern. In an example embodiment, the lower support pad 142 may have a rectangular shape, a polygonal shape, a circular shape, or an elliptical shape. For ease of description, the lower support pads 142 are illustrated in FIG. 6. However, as illustrated in FIG. 5, the lower support pads 142 may be entirely covered by the lower protective layer 150.

The lower support pad 122 may include, for example, a metal material including copper (Cu), aluminum (Al), silver (Ag), tin (Sn), gold (Au), nickel (Ni), lead (Pb), titanium (Ti), or alloys thereof. In an example embodiment, the lower support pad 142 may be formed simultaneously with the dummy through-via V2, and may include a material the same as that of the dummy through-via V2 (e.g., the lower support pad 142 may be formed in the same process as the dummy through-via V2). In an example embodiment, the lower support pad 142 may have a thickness substantially equal to that of the lower connection pad 140. The lower support pad 142 may be referred to as a lower support structure.

As described above, in a PCB for an MUF, an area of the upper protective layer 130 (or a volume of the upper protective layer 130) may be formed to be relatively less than an area of the lower protective layer 150 (or a volume of the lower protective layer 150), and thus coefficients of thermal expansion (CTE) of the upper structure US and the lower structure LS may be different from each other. Accordingly, when the different coefficients of thermal expansion are not compensated for, the substrate 100 may be bent due to the upper structure US and the lower structure LS having different coefficients of thermal expansion.

However, as illustrated in FIGS. 4 to 6, the core layer 110 of the substrate 100 according to example embodiments of the present inventive concept may include a dummy through-via V2 in the dummy region R2, and may include an upper support pad 122 and a lower support pad 142 connected to the dummy through-via V2. The dummy through-via V2 may be connected to both the upper support pad 122 of the upper structure US and the lower support pad 142 of the lower structure LS, such that bending of the substrate 100 may be prevented or reduced even when the coefficients of thermal expansion of the structure US and the lower structure LS are different from each other.

In addition, according to example embodiments of the present inventive concept, in the dummy region R2, a pattern density of the upper structure US may be greater than that of the lower structure US. Here, the pattern density of the upper structure US may refer to a ratio of an area of the upper support pads 122 and the upper support patterns 124 to a total area (for example, an area of the core layer 110 or the upper protective layer 130) in plan view (see FIG. 4). The pattern density of the lower structure US may refer to a ratio of an area of the lower support pads 142 to a total area (for example, an area of the core layer 110 or the lower protective layer 150) in plan view (see FIG. 6). That is, the upper support pads 122 and the upper support patterns 124 may be disposed more densely than the lower support pads 142.

In an example embodiment, a pattern density of the upper structure US in the dummy region R2 may be greater than a pattern density of the upper structure US in the active region R1. The pattern density of the upper structure US in the active region R1 may refer to a ratio of an area of the upper connection pads 120 to a total area (for example, an area of the core layer 110) in plan view (FIG. 2).

In an example embodiment, the upper support pad 122 may be greater than the upper connection pad 120. For example, a horizontal width Wb of the upper support pad 122 may be greater than a horizontal width Wa of the upper connection pad 120. In an example embodiment, the upper support pad 122 may be greater than the lower support pad 142. For example, the horizontal width Wb of the upper support pad 122 may be greater than a horizontal width Wc of the lower support pad 142. In an example embodiment, the horizontal width Wc of the lower support pad 142 may be less than the horizontal width Wa of the upper connection pad 120. The horizontal width Wb of the upper support pad 122 and the horizontal width Wc of the lower support pad 142 may be greater than a horizontal width of the dummy through-via V2. A horizontal width of the upper support pattern 124 may be less than the horizontal width Wb of the upper support pad 122. A distance Wd between the upper support pads 122 may be less than a distance We between the lower support pads 142.

In an example embodiment, the horizontal width Wb of the upper support pad 122 may be in a range from about 150μm to about 400μm. The horizontal width Wc of the lower support pad 142 may be in a range from about 100μm to about 150μm. The distance Wd between the upper support pads 122 may be in a range from about 100μm to about 350μm. The distance We between the lower support pads 142 may be in a range from about 350μm to about 400μm.

As described, the pattern density of the upper structure US in the dummy region R2 may be formed to be greater than the pattern density of the upper structure US in the active region R1, and the pattern density of the upper structure US in the dummy region R2 may be formed to be greater than a pattern density of the lower structure LS in the dummy region R2, thereby reducing a difference between the coefficients of thermal expansion of the upper structure US and the lower structure LS of the entire substrate 100, and preventing or reducing bending of the substrate 100.

As described above, the area of the upper protective layer 130 may be formed to be relatively less than the area of the lower protective layer 150, and the coefficient of thermal expansion of the upper structure US may be different from the coefficient of thermal expansion of the lower structure LS. However, according to example embodiments of the present inventive concept, the upper support pads 122 may be connected to each other by the upper support patterns 124, thereby preventing or reducing bending of the upper structure US.

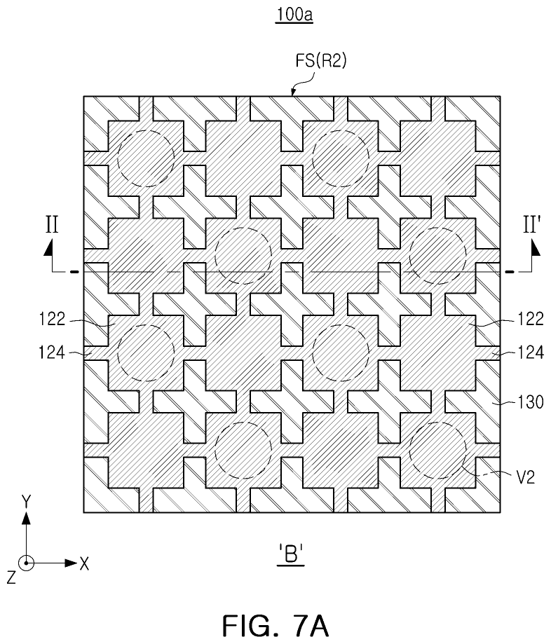

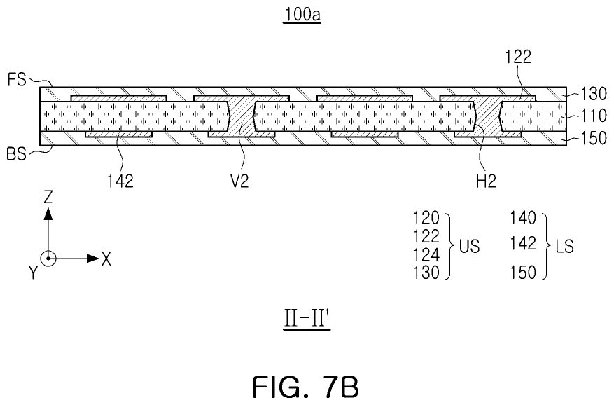

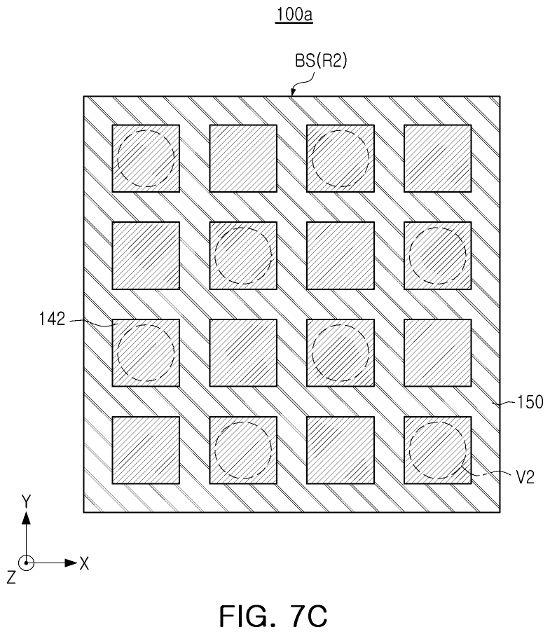

FIG. 7A is a plan view of a substrate according to an example embodiment. FIG. 7B is a vertical cross-sectional view of the substrate illustrated in FIG. 7A, taken along line II-II′. FIG. 7C is a plan view of the substrate illustrated in FIG. 7B. FIG. 7A illustrates a front surface FS of the substrate illustrated in FIG. 7B, and FIG. 7C illustrates a rear surface BS of the substrate illustrated in FIG. 7B.

Referring to FIGS. 7A to 7C, a substrate 100a may include dummy through-vias V2 disposed in a dummy region R2. In an example embodiment, the dummy through-via V2 may be omitted between an upper support pad 122 and a lower support pad 142 in the dummy region R2. For example, at least one of the upper support pads 122 or at least one of the lower support pads 142 may not be in contact with the dummy through-via V2. For example, the upper support pads 122 and the lower support pads 142 may include first and second upper support pads 122 and first and second lower support pads 142, respectively. The first upper support pad 122 and the first lower support pad 142 may be connected to each other through the dummy through-via V2, and the second upper support pad 122 may not be connected to the second lower support pad 142. A core layer 110 may be interposed between the second upper support pad 122 and the second lower support pad 142. An arrangement structure of the dummy through-vias V2 illustrated in FIG. 7A is example, and is not limited thereto.

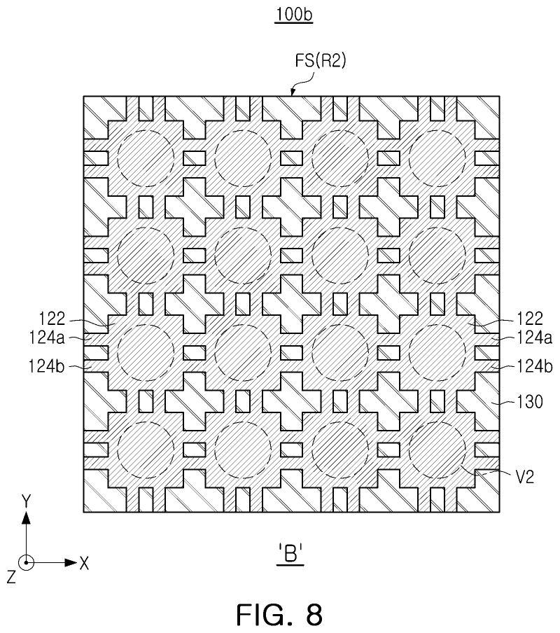

FIGS. 8 to 10 are plan views of a substrate according to example embodiments.

Referring to FIG. 8, a substrate 100b may include upper support pads 122 and upper support patterns 124a and 124b disposed in a dummy region R2. In an example embodiment, a plurality of upper support patterns 124a and 124b may be connected to each of the upper support pads 122. For example, upper support pads 122, adjacent to each other, may be connected by a first upper support pattern 124a and a second upper support pattern 124b.

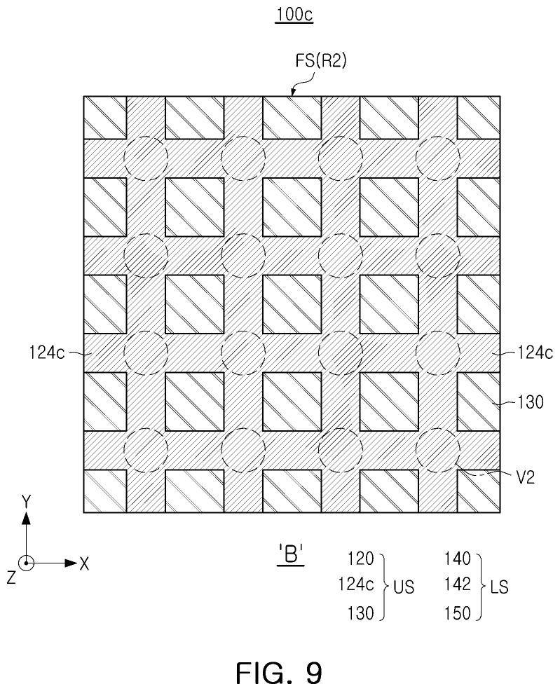

FIG. 9 illustrates a front surface of a substrate according to an example embodiment.

Referring to FIG. 9, an upper structure US of a substrate 100c may include an upper support structure 124c. The upper support structure 124c may be an example embodiment in which an arrangement structure is modified such that an upper support pad 122 and an upper support pattern 124 illustrated in FIG. 4 have an equal width. The upper support structure 124c may have a grid shape, and may extend in a horizontal direction.

In an example embodiment, the rear surface BS of the substrate 100c may also have a structure similar to or the same as that of the front surface FS. For example, the lower support pad 142 of the lower structure LS may have a grid shape and may extend in a horizontal direction.

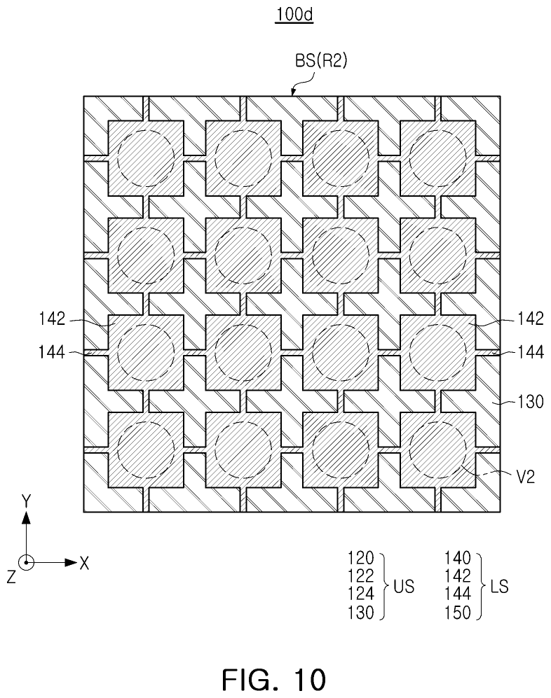

FIG. 10 illustrates a front surface of a substrate according to an example embodiment.

Referring to FIG. 10, a lower structure LS of a substrate 100d may include lower support structures. The lower support structure may include a lower support pad 142 and a lower support pattern 144. For example, the lower support patterns 144 may extend in a horizontal direction between the lower support pads 142, and may connect adjacent lower support pads 142 to each other. A horizontal width of the lower support pattern 144 may be less than or equal to a horizontal width of the lower support pad 142. The horizontal width of the lower support pattern 144 may be less than or equal to a horizontal width of an upper support pattern 124.

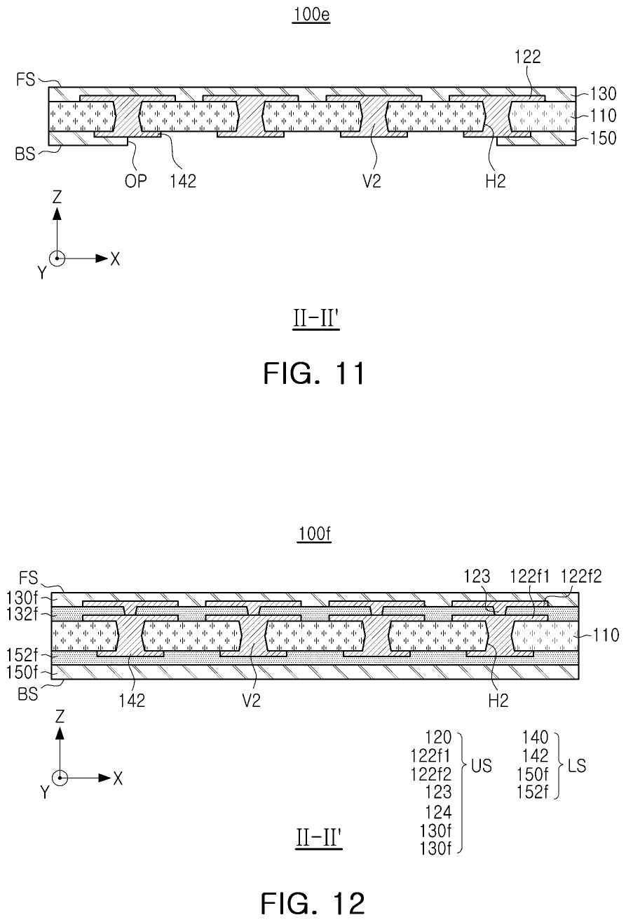

FIGS. 11, 12 and 13A to 13D are vertical cross-sectional views of a substrate according to example embodiments.

Referring to FIG. 11, a lower structure LS of a substrate 100e may include a lower protective layer 150 covering a lower surface of a core layer 110. In an example embodiment, the lower protective layer 150 may have an opening OP in a dummy region R2. For example, the opening OP may expose the lower surface of the core layer 110 and/or a lower support pad 142.

In a structure of a PCB for an MUF, when the opening OP is formed in a lower surface of the lower protective layer 150 in the dummy region R2 to compensate for an area of an upper protective layer 130 in an active region R1 being formed relatively less than an area of the lower protective layer 150 in the active region R1, a difference between coefficients of thermal expansion of an upper structure US and a lower structure LS may be reduced, and bending of the substrate 100e may be prevented or reduced.

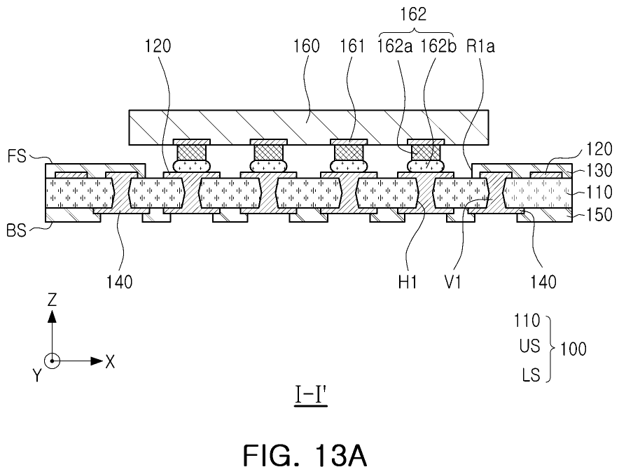

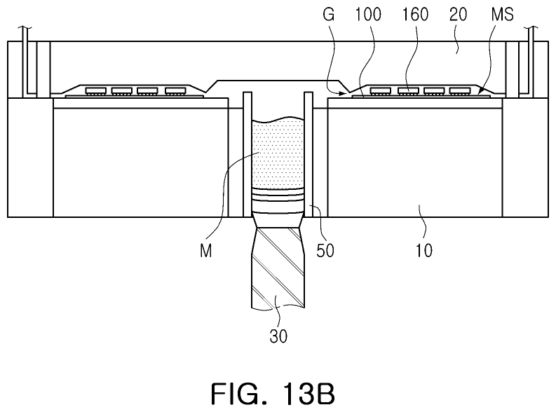

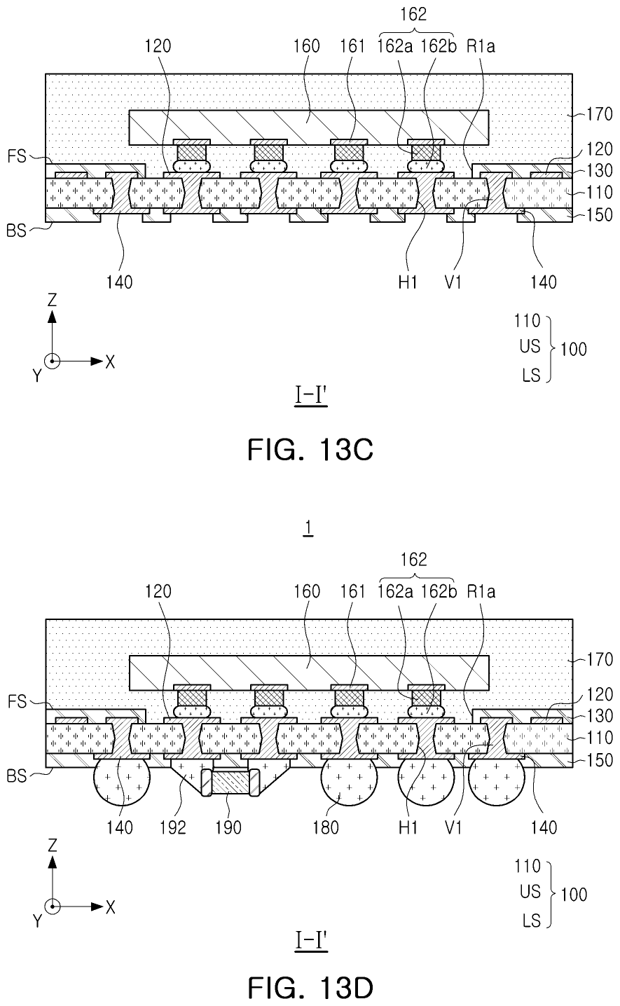

FIGS. 12 and 13A to 13D illustrate vertical cross-sectional views of a substrate in a dummy region R2 according to an example embodiment.

Referring to FIG. 12, a substrate 100f may include an upper structure US and a lower structure LS disposed on upper and lower surfaces of a core layer 110. In an example embodiment, the upper structure US and the lower structure LS may be formed of a plurality of layers. For example, in the dummy region R2, the upper structure US may include a first upper support pad 122f1, a second upper support pad 122f2, a connection via 123, an upper protective layer 130f, and an insulating layer 132f. The first upper support pad 122f1 may be in contact with a dummy through-via V2, and the second upper support pad 122f2 may be disposed on the first upper support pad 122f1. The connection via 123 may connect the first upper support pad 122f1 and the second upper support pad 122f2 to each other.

In an example embodiment, the first upper support pad 122f1 and/or the second upper support pad 122f2 may have an arrangement and/or a structure the same as that illustrated in FIG. 4 or 9. The first upper support pad 122f1, the second upper support pad 122f2, and the connection via 123 may include a material the same as that of the dummy through-via V2.

The insulating layer 132f may cover the upper surface of the core layer 110, and may cover the first upper support pad 122f1 and the connection via 123. The upper protective layer 130f may be disposed on the insulating layer 132f, and may cover the second upper support pad 122f2.

The insulating layer 132f may include an insulating resin and an inorganic filler. For example, the insulating layer 132f may include an ABF, but the present inventive concept is not limited thereto, and the insulating layer 132f may include a photosensitive insulating material (PID) or an insulating polymer, for example, photosensitive polyimide (PSPI). The upper protective layer 130f may include a solder resist.

A structure of the upper structure US illustrated in FIG. 12 is an example, and is not limited thereto. For example, the upper structure US may include a plurality of insulating layers 132f between the core layer 110 and the upper protective layer 130f, and each of the insulating layers 132f may cover an upper support pad.

In an example embodiment, the lower structure LS may include a lower protective layer 150f and an insulating layer 152f in the dummy region R2. The insulating layer 152f may cover the lower surface of the core layer 110, and may cover the lower support pad 142. The lower protective layer 150f may be disposed below the insulating layer 152f. The lower protective layer 150f and the insulating layer 152f may include materials the same as those of the upper protective layer 130f and the insulating layer 132f, respectively.

As illustrated in FIG. 12, the upper structure US may include a first upper support pad 122f1 and a second upper support pad 122f2, forming a plurality of layers, and the lower structure LS may include a single-layered lower support pad 142, thereby compensating for an area of an upper protective layer 130 formed to be relatively less than an area of a lower protective layer 150 in an active region R1, reducing a difference between coefficients of thermal expansion of the upper structure US and the lower structure LS, and preventing or reducing bending of the substrate 100f. In an example embodiment, the lower support pads 142 of the lower structure LS may form a plurality of layers. For example, the number of the lower support pads 142 may be equal to or less than the number of upper support pads of the upper structure US.

FIGS. 13A to 13D are diagrams illustrating a method of manufacturing a semiconductor package according to an example embodiment. FIGS. 13A to 13D illustrate an active region of a substrate.

Referring to FIG. 13A, a semiconductor chip 160 may be mounted on a substrate 100. The semiconductor chip 160 may be electrically connected to the substrate 100 by a bump structure 162. For example, the semiconductor chip 160 may include a chip pad 161 connected to the bump structure 162. The chip pad 161 may be disposed on a lower surface of the semiconductor chip 160, and may be in contact with the corresponding bump structure 162. For example, the bump structure 162 may have a solder ball, a conductive bump, or a flip-chip connection structure having a grid array such as a pin grid array, a ball grid array, or a land grid array.

The bump structures 162 may include a first portion 162a in contact with the chip pads 161, and a second portion 162b connecting the first portion 1622a and an upper connection pad 120 to each other. For example, the first portion 162a may be a metal post portion, and the second portion 162b may be a solder portion including a low melting point metal, but the present inventive concept is not limited thereto. In some example embodiments, the bump structures 162 may include only the second portion 162b. The low melting point metal may include tin (Sn), indium (In), bismuth (Bi), antimony (Sb), copper (Cu), silver (Ag), zinc (Zn), lead (Pb), or alloys thereof (for example, Sn—Ag—Cu).

The semiconductor chip 160 may be a logic chip or a memory chip. The logic chip may include a microprocessor, an analog device, or a digital signal processor. The memory chip may include a volatile memory chip such as a dynamic random access memory (DRAM) or a static random access memory (SRAM), or a nonvolatile memory chip such as a phase-change random access memory (PRAM), a magnetoresistive random access memory (MRAM), a ferroelectric random access memory (FeRAM), or a resistive random access memory (RRAM).

Referring to FIGS. 13B and 13C, a molding-type mold may include a lower mold 10 and an upper mold 20. A port 50 for supplying a molding material M may be disposed in a central portion of the lower mold 10. A molding space MS may be defined between the lower mold 10 and the upper mold 20. The molding space MS may be disposed on opposite sides of the port 50, and may extend in a horizontal direction.

The molding material M may be supplied to the molding space MS through a gate G by a vertical reciprocating motion of a ram 30 disposed in the port 50. A molding process may be simultaneously performed in the molding space MS disposed on the opposite sides of the port 50.

The substrate 100 on which the semiconductor chip 160 is mounted may be disposed in the molding space MS. The molding material M, supplied through the gate G, may cover the substrate 100 and the semiconductor chip 160. The molding material M may be cured to form an encapsulant 170 illustrated in FIG. 13C.

The encapsulant 170 may cover the substrate 100 and the semiconductor chip 160. The encapsulant 170 may be a resin including epoxy, polyimide, or the like. For example, the resin may include a bisphenol-group epoxy resin, a polycyclic aromatic epoxy resin, an o-cresol novolac epoxy resin, a biphenyl-group epoxy resin, or a naphthalene-group epoxy resin.

Referring to FIG. 13D, an external connection terminal 180 may be formed below the substrate 100, and a semiconductor package 1 may be manufactured by performing a sawing process. The external connection terminal 180 may be in contact with a lower connection pad 140. A ground voltage Vss or a power supply voltage Vdd may be applied to the lower connection pad 140. The external connection terminal 180 may be electrically connected to an external device such as a main board or the like. The external connection terminal 180 may include a conductive material, and may be in the form of a ball, a pin, or a lead. For example, the external connection terminal 180 may be a solder ball.

The semiconductor package 1 may further include a passive device 190 and a connection terminal 192, disposed below the substrate 100. The passive device 190 may be electrically connected to a corresponding lower connection pad 140, among the lower connection pads 140, through the connection terminal 192. The passive device 190 may include, for example, a capacitor such as a multilayer ceramic capacitor (MLCC) or a low inductance chip capacitor (LICC), an inductor, a bead, or the like. In an example embodiment, the passive device 190 may be a land-side capacitor (LSC). However, the present inventive concept is not limited thereto. In some example embodiments, the passive device 190 may be a die-side capacitor (DSC) mounted on an upper surface of the substrate 100 or an embedded-type capacitor embedded in the substrate 100.

The sawing process may be performed by cutting the substrate 100 along the scribe lane SL illustrated in FIG. 1, and each active region R1 may be individualized to form the semiconductor package 1.

According to example embodiments of the present inventive concept, a dummy through-via and an upper support pad and a lower support pad, connected thereto, may be disposed in a dummy region, thereby reducing a difference in thermal expansion coefficients between an upper structure and a lower structure of a substrate, and preventing warpage of the substrate.

While example embodiments have been shown and described above, it will be apparent to those skilled in the art that modifications and variations could be made without departing from the scope of the present inventive concept as defined by the appended claims.

What is claimed is:

1. A substrate comprising:
a core layer including an active region in which a semiconductor chip is mounted and a dummy region, surrounding the active region;
through-vias disposed in the active region, the through-vias passing through the core layer;
dummy through-vias disposed in the dummy region, the dummy through-vias passing through the core layer;
upper connection pads disposed on an upper surface of the core layer in the active region, each of the upper connection pads electrically connected to a respective one of the through-vias;
upper support pads disposed on the upper surface of the core layer in the dummy region, each of the upper support pads in contact with a respective one of the dummy through-vias; and
lower support pads disposed on a lower surface of the core layer in the dummy region, each of the lower support pads in contact with a respective one of the dummy through-vias.

2. The substrate of claim 1, further comprising:
upper support patterns connecting the upper support pads to each other in the dummy region.

3. The substrate of claim 1, wherein a size of each of the upper support pads is greater than a size of each of the lower support pads.

4. The substrate of claim 1, wherein a size of each of the lower support pads is less than a size of each of the upper connection pads.

5. The substrate of claim 1, wherein a distance between adjacent ones of the upper support pads is less than a distance between adjacent ones the lower support pads.

6. The substrate of claim 1, further comprising:
an upper protective layer disposed on the upper surface of the core layer,
wherein the upper protective layer partially covers the active region and entirely covers the dummy region, and
at least one of the upper connection pads is exposed by the upper protective layer.

7. The substrate of claim 1, further comprising:
a lower protective layer disposed on the lower surface of the core layer,
wherein the lower protective layer partially covers the active region and entirely covers the dummy region.

8. The substrate of claim 7, further comprising:
lower connection pads disposed on the lower surface of the core layer in the active region, each of the lower connection pads electrically connected to a respective one of the through-vias, and
at least one of the lower connection pads is exposed by an opening in the lower protective layer.

9. The substrate of claim 1, wherein a pattern density of the upper support pads is greater than a pattern density of the lower support pads.

10. The substrate of claim 1, wherein a pattern density of each of the upper connection pads is less than a pattern density of each of the upper support pads, and is greater than a pattern density of each of the lower support pads.

11. The substrate of claim 1, wherein one of the upper support pads is not in contact with the dummy through-vias.

12. The substrate of claim 1, further comprising:
lower support patterns connecting the lower support pads to each other in the dummy region.

13. The substrate of claim 1, wherein
a horizontal width of each of the upper support pads is in a range of 150μm to 400 μm, and
a horizontal width of each of the lower support pads is in a range of 100μm to 150 μm.

14. The substrate of claim 1, wherein
a distance between adjacent ones of the upper support pads is in a range of 100 μm to 350μm, and
a distance between adjacent ones of the lower support pads is in a range of 350 μm to 400μm.

15. The substrate of claim 1, further comprising:
a lower protective layer disposed on the lower surface of the core layer,
wherein the lower protective layer exposes at least one of the lower support pads.

16. The substrate of claim 1, wherein
the upper support pads include a first upper support pad in contact with a respective one of the dummy through-vias and a second upper support pad on the first upper support pad, and
the substrate further includes a connection via connecting the first upper support pad and the second upper support pad to each other.

17. A substrate comprising:
a core layer including an active region in which a semiconductor chip is mounted and a dummy region, surrounding the active region;
through-vias disposed in the active region, the through-vias passing through the core layer;
dummy through-vias disposed in the dummy region, the dummy through-vias passing through the core layer;
an upper structure disposed on an upper surface of the core layer; and
a lower structure disposed on a lower surface of the core layer,
wherein the upper structure includes upper connection pads, each of the upper connection pads in contact with a respective one of the through-vias, and an upper support structure in contact with the dummy through-vias, and
the lower structure includes a lower support structure in contact with the dummy through-vias.

18. The substrate of claim 17, wherein the upper support structure includes upper support pads, each of the upper support pads in contact with a respective one of the dummy through-vias, and upper support patterns connecting the upper support pads to each other.

19. The substrate of claim 17, wherein the upper support structure has a grid shape.

20. A substrate comprising:
a core layer including an active region in which a semiconductor chip is mounted and a dummy region, surrounding the active region;
through-vias disposed in the active region, the through-vias passing through the core layer;
dummy through-vias disposed in the dummy region, the dummy through-vias passing through the core layer;
upper connection pads disposed on an upper surface of the core layer in the active region, each of the upper connection pads electrically connected to a respective one of the through-vias;
upper support pads disposed on the upper surface of the core layer in the dummy region, each of the upper support pads in contact with a respective one of the dummy through-vias; and
lower support pads disposed on a lower surface of the core layer in the dummy region, each of the lower support pads in contact with a respective one of the dummy through-vias,
wherein the core layer includes dummy through-holes passing through the core layer in the dummy region,
each of the dummy through-vias fill a respective one of the dummy through-holes, and
the dummy through-vias have a first width at a first vertical level, a second width greater than the first width at a second vertical level higher than the first vertical level, and a third width greater than the first width at a third vertical level lower than the first vertical level.
